(19) United States
(12) Patent Application Publication
(10) Pub. No.: US 2025/0084537 A1
(43) Pub. Date: Mar. 13, 2025

(54) DECORATIVE ANTIQUE COPPER COATING WITH HTL COMPATIBILITY AND NOVEL INTER-LAYER ADHESION MECHANISM

(71) Applicant: Motherson Innovations Company Limited, London (GB)

(72) Inventors: Simon David FIELD, Lonsdale (AU); Scott EDWARDS, Lonsdale (AU); Bastian STOEHR, Lonsdale (AU)

(21) Appl. No.: 18/960,027

(22) Filed: Nov. 26, 2024

Related U.S. Application Data
(63) Continuation-in-part of application No. PCT/EP2023/064243, filed on May 26, 2023.

(30) Foreign Application Priority Data
May 30, 2022 (DE) 10 2022 113 597.7

(51) Int. Cl. C23C 28/04; C23C 14/06; C23C 14/34; C23C 16/40; C23C 16/50

(52) U.S. Cl. CPC C23C 28/04; C23C 14/0641; C23C 14/34; C23C 16/402; C23C 16/50

(57) ABSTRACT

An article having a decorative coating includes a plastic substrate having a front surface, a base hardcoating located over the front surface, one or more intermediate layers located over the hardcoating, a TiN layer located over the one or more intermediate layers, an SiO₂ layer or PECVD HMDSO+O₂ etch layer located over the TiN layer, and a protective hardcoating located over the PECVD HMDSO+O₂ etch layer.

### CROSS-REFERENCE TO RELATED APPLICATIONS

This application is a continuation-in-part (CIP) of International (PCT) Application Number PCT/EP2023/064243, filed on May 26, 2023, which claims priority to German Patent Application No. DE 10 2022 113 597.7, filed on May 30, 2022, each of which are incorporated herein by reference.

### FIELD

The present invention relates to decorative coatings for substrates, the decorative coatings being stable and durable coatings that are spectrally tunable to permit the selection of a variety of appearances, in particular having a (antique) copper like metal finish. The present invention also provides a novel inter-layer adhesion mechanism to provide a more cost effective and technically suitable preparation process.

### BACKGROUND

Decorative coatings, especially decorative metal finishes, are becoming increasingly desirable as designer surfaces on a variety of consumer goods including premium automotive interior and exterior trim components, consumer and household goods, as well as fashionable household electronic products, and either as partial or full surfaces for those goods.

While bulk metal can be used for such applications, it is not only heavy and cumbersome to work with, but also difficult and expensive to machine and polish into the complex shapes that are common across these types of components. In addition, bulk metal does not support ‘surprise and delight’ hidden lighting, or back lighting in general, nor does it lend itself to the formation of a surface where a part of the surface has a different appearance to another part of the surface. Thus, it tends to be more desirable to utilize light substrates, such as for example plastic substrates. Such plastic components have many additional attractive properties including resistance to breaking, low cost, ability to be shaped and molded and in some applications their transparency. However, such plastic components do not necessarily meet the visual requirements and wear requirements needed for automotive applications. By coating plastic substrates (with metallic coatings), components can be provided which meet the desired visual aesthetic while also improving the wear resistance of the underlying plastic substrate.

The metallic coatings should possess tunable properties to offer durable, decorative finishes that also allow light transmission. The coatings should offer the ability to converge the need for spectral and optical tunability with metallic finishes to create functional, highly durable, customizable surfaces (for example) from bright through to deep black colors with backlighting functionality if desired.

OEMs are always looking for ways to make their vehicle stand out from the crowd. In styling terms this can mean the use of certain color trim throughout the vehicle to give it a different and/or premium look. For example, providing an (antique) copper color may be desirable for specific applications, such as in vehicles. PVD coatings using Cu are not satisfactory in this regard as the coatings may have the appearance of bright, un-tarnished copper. Such coatings are often susceptible to significant color changes during the thermal curing operation of the protective topcoat (both the temperature and time are critical) and are also susceptible to corrosion during neutral salt spray tests. Also, traditional combinations of Si and Cr based materials may provide a similar copper color but the color is too angular dependent, i.e. such coatings change color upon being rotated through different viewing angles, which is unfavorable, i.e. the appearance is different than desired. Thus, combinations of several metals or mixtures thereof need to be employed to achieve a desired color, such as an (antique) copper color.

However, preparing coatings from different metals or mixtures of metals makes it difficult to simultaneously prepare additional adhesive layers, which might be necessary to apply and adhere protective top coatings.

There is thus a need for a durable, spectrally tunable surface for plastic substrates that allows for the selection of broad ranges of appearance, such as a copper color, that can be substantially transparent so as to permit hidden lighting functionality if desired and that can easily be prepared by obtaining excellent adhesive properties of the applied layers.

The above discussion of background is included to explain the context of the present invention. It is not to be taken as an admission that any of the material referred to was published, known, or part of the common general knowledge at the priority date of any one of the claims.

### SUMMARY

Embodiments of the present disclosure provide an article having a decorative coating, wherein the article comprises:
a plastic substrate having a front surface;
an optional base hardcoating located over the front surface;
one or more intermediate layers located over the hardcoating;
a TiN layer located over the one or more intermediate layers;
an SiO₂ layer or PECVD HMDSO+O₂ etch layer located over the TiN layer; and
a protective hardcoating located over the SiO₂ or PECVD HMDSO+O₂ etch layer.

Embodiments of the present disclosure also provide an article that is used for automotive applications.

Also provided herein is a method of manufacturing an article, the method comprises the steps of:
a) forming a plastic substrate having a front surface;
b) optionally coating a hardcoating onto the front surface of the substrate;
c) forming one or more intermediate layers on the hardcoating;
d) coating a TiN layer onto the one or more intermediate layers;
e) coating a SiO₂ layer or a layer using PECVD HMDSO+O₂ etching technology on the TiN layer; and
f) coating a protective hardcoating layer on the layer prepared in step e).

With embodiments of the present disclosure, a “desired optical effect” may be achieved. The desired optical effect has an impact upon how the decorative coating is spectrally tuned to provide the coated substrate with that desired optical effect.

The desired optical effect may be a desired appearance for a surface, or a part of a surface, of a product (when viewed from the front) that includes a coated substrate in accordance with embodiments of the present disclosure. The desired optical effect may be made up of a combination of a desired transmitted color, a desired specular reflected color, and a desired diffuse reflected color, taking account of the combined influence of the decorative coating, the plastic substrate and the presence or not of backlighting. In this respect, the plastic substrate needs to be taken into account as the substrate may itself be tinted or clear, or may include embedded particles to provide the uncoated substrate with a hazy appearance, or may have one or both of its (uncoated) surfaces bearing a texture such as might be adopted to provide a “brushed-metal” appearance. While all of these attributes will contribute to the overall appearance of the final product, it should be appreciated that in embodiments of the present disclosure it is the decorative coating that is tunable to permit the achievement of the desired optical effect.

In relation to a determination of a desired transmitted color, a desired specular reflected color, and a desired diffuse reflected color, reference throughout this specification to a “color” is reference to a color that is defined by measured L*, a* and b* values in accordance with the 1976 CIE L*a*b* Space (or CIELAB) color model, which is an approximately uniform color scale organized in cube form. In the orthogonal a* and b* color axes, positive a* values are red, negative a* values are green, positive b* values are yellow and negative b* values are blue, while the vertical scale for lightness (or greyscale) L* runs from 0 (black) to 100 (white), allowing the positioning of a total color E in three points. The Chroma (C*) of the color is defined as √(a*²+b*²), and is used to quantify the magnitude of the color independent of its lightness.

It will also be appreciated that reference to “transmitted” color and “reflected” color are references to the color of light after having been transmitted through an object (“transmitted color”) or after having been reflected by the surface of an object (“reflected color”). Furthermore, with respect to reflected color, “specular reflection” is a reference to the mirror-like reflection of light from the surface of an object, in which light from a single incoming direction is reflected into a single outgoing direction, whereas “diffuse reflection” is of course a reference to incoming light being reflected in a broad range of directions.

Embodiments of the present disclosure also provides a method for applying a decorative coating to a plastic substrate, the decorative coating providing the coated substrate with a desired optical effect, the method including:
a) determining the desired optical effect;
b) determining a suitable system that will provide the desired optical effect;
c) coating the suitable system upon the substrate;
d) thereby forming a coated plastic substrate with the desired optical effect.

### BRIEF DESCRIPTION OF THE DRAWINGS

Embodiments of the present disclosure will be discussed by way of example with reference to the accompanying drawings, wherein:

FIGS. 1a to 1c show a schematic representation of a coated plastic substrate in accordance with first to third embodiments of the present disclosure, showing articles having a decorative coating which provides an antique copper color.

FIG. 1d shows a schematic representation of a coated plastic substrate in accordance with a further embodiment of the present disclosure, showing a hardcoat not necessarily providing a satin effect.

FIG. 2 shows a color match chart for an antique copper color coating.

### DETAILED DESCRIPTION

Embodiments of the present disclosure relate to an article having a decorative coating, wherein the article comprises:
a plastic substrate having a front surface;
an optional base hardcoating located over the front surface;
one or more intermediate layers located over the hardcoating;
a TiN layer located over the one or more intermediate layers;
an SiO₂ layer or PECVD HMDSO+O₂ etch layer located over the TiN layer; and. a protective hardcoating located over the SiO₂ or PECVD HMDSO+O₂ etch layer.

The substrate may be formed from any suitable plastic material. For example, a plastic substrate may be formed from a material selected from the group including, but not limited to, acrylonitrile ethylene styrene (AES), acrylonitrile butadiene styrene (ABS), acrylonitrile styrene acrylate (ASA), polyamide (PA), polybutylene terephthalate (PBT), polycarbonate (PC), polyethylene (PE), polyethylene terephthalate (PET), poly(methyl methacrylate) (PMMA), Polyoxymethylene (POM), Polypropylene (PP), Polyurethane (PU), polyvinylchloride (PVC), high-flow AES, acrylonitrile-(ethylene-propylene-diene)-styrene (AEPDS), blends of thermoplastics, or PC-ABS blended thermoplastic. In one preferred embodiment the plastic substrate is made from polycarbonate. In preferred forms, the substrate will typically have a physical thickness in the range of 0.1 mm to 20 mm, more preferably in the range of 1 mm to 5 mm, and most preferably in the range of 2 mm to 3 mm, but is not limited to.

In some embodiments, the provided plastic substrate may comprise visible texturing prior to deposition of the decorative coating. In some embodiments, the present invention further includes providing a visible texturing to the plastic substrate. In certain embodiments, the plastic substrate is provided with, or comprises, two or more visually distinct textures.

An article bearing the decorative coating of the present invention may also optionally comprise a base hardcoating between the decorative coating and the substrate. The base hardcoating may be a protective layer which may not contribute to the overall desired optical effect, while in other embodiments an external protective layer upon the decorative coating will itself be a hardcoating. Alternatively, the base hardcoating may also contribute to the desired optical effect. The base hardcoating may be used to prevent UV radiation damage. This blocks the UV generated during plasma treatment thereby allowing for the advantages of plasma pre-treatment without the UV degradation. In one embodiment, the base hardcoating is not present. In a further embodiment, the base hardcoating is present.

In this respect, a coating that is said to be a “hardcoating” is a coating that is harder and stiffer than the substrate, whereby it increases the abrasion resistance of that substrate. Such an abrasion resistant hard coating is one that reduces damage due to impacts and scratching. Abrasion resistance can be measured through tests such as ASTM F735 “Standard Test Method for Abrasion Resistance of Transparent Plastics and Coatings Using the Oscillating Sand Method”, ASTM D4060 “Standard Test Method for Abrasion Resistance of Organic Coatings”, by the Taber Abrader, or by using the well-known Steelwool Test.

Furthermore, some plastic substrates can be damaged by certain solvents; for example, polycarbonate is damaged by acetone. It is a requirement for many products that might be suited to the decorative coating of the present invention that they be “chemically resistant”, which is a reference to an ability to withstand exposure to normal solvents such as diesel fuel, petroleum, battery acid, brake fluid, antifreeze, acetone, alcohol, automatic transmission fluid, hydraulic oil and ammonia based window cleaners. In this respect, it will be appreciated that a hardcoating ideally provides a product bearing the decorative coating of the present invention with such chemical resistance.

A hardcoating is preferably formed from one or more abrasion resistant layers, and may include a primer layer that bonds well to a plastic substrate and forms a preferable material for subsequent abrasion resistant layers. The primer layer may be provided by any suitable material and may for example be an organic resin such as an acrylic polymer, a copolymer of acrylic monomer and methacryloxysilane, or a copolymer of a methacrylic monomer and an acrylic monomer having a benzotriazole group or benzophenone group. These organic resins may be used alone or in combinations of two or more.

The abrasion resistant layers are preferably formed from one or more materials selected from the group consisting of an organo-silicon, an acrylic, a urethane, a melamine or an amorphous SiOₓC_{y}H_{z}. Most preferably, the abrasion resistant layer is an organo-silicon layer, due to its superior abrasion resistance and compatibility with physical vapor deposited films. For example, an abrasion resistant layer comprising an organo-silicon polymer can be formed by forming a layer of a compound selected from the following compounds by a method such as dip coating or the like and then curing the layer: trialkoxysilanes or triacyloxysilanes such as methyltrimethoxysilane, methyltricthoxysilane, methyltrimethoxyethoxysilane, methyltriacetoxysilane, methyltripropoxysilane, methyltributoxysilane, ethyltrimethoxysilane, ethyltricthoxysilane, vinyltrimethoxysilane, vinyltricthoxysilane, vinyltriacetoxysilane, vinyltrimethoxyethoxysilane, phenyltrimethoxysilane, phenyltriethoxysilane, phenyltriacetoxysilane, gamma-chloropropyltrimethoxysilane, gamma-chloropropyltriethoxysilane, gamma-chloropropyltripropoxysilane, 3,3,3-trifluoropropyltrimethoxysilane gamma-glycidoxypropyltrimethoxysilane, gamma-glycidoxypropyltriethoxysilane, gamma-(beta-glycidoxyethoxy)propyltrimethoxysilane, beta-(3,4-epoxycyclohexyl)ethyltrimethoxysilane, beta-(3,4-epoxycyclohexyl)ethyltriethoxysilane, gamma-methacryloxypropyltrimethyoxysilane, gamma-aminopropyltrimethoxysilane, gamma-aminopropyltriethoxysilane, gamma-meraptopropyltrimethoxysilane, gamma-mercaptopropyltriethoxysilane, N-beta(aminoethyl)-gamma-aminopropyltrimethoxysilane, beta-cyanoethyltriethoxysilane and the like; as well as dialkoxysilanes or diacyloxysilanes such as dimethyldimethoxysilane, phenylmethyldimethoxysilane, dimethyldiethoxysilane, phenylmethyldicthoxysilane, gamma-glycidoxypropylmethyldimethoxysilanc, gamma-glycidoxypropylmethyldicthoxysilane, gamma-glycidoxypropylphenyldimethoxysilane, gamma-glycidoxypropylphenyldicthoxysilane, gamma-chloropropylmethyldimethoxysilane, gamma-chloropropylmethyldiethoxysilane, dimethyldiacetoxysilane, gamma-methacryloxypropylmethyldimethoxysilane, gamma-metacryloxypropylmethyldiethoxysilane, gamma-mercaptopropylmethyldimethoxysilane, gamma-mercaptopropylmethyldiethoxysilane, gamma-aminopropylmethyldimethoxysilane, gamma-aminopropylmethyldiethoxysilane, methylvinyldimethoxysilane, methylvinyldicthoxysilane and the like.

The abrasion resistant layers may be coated onto a plastic substrate by dip coating in liquid followed by solvent evaporation, or by plasma enhanced chemical vapour deposition (PECVD) via a suitable monomer. Alternative deposition techniques such as flow coating and spray coating are also suitable. To improve the abrasion resistance of the hardcoating, subsequent coatings of the abrasion resistant layer may be added, preferably within a 48 hour period to as to avoid aging and contamination of the earlier coatings.

The thickness of an abrasion resistant layer is preferably selected to assist in providing adequate abrasion resistance. In this respect, adequate abrasion resistance is regarded herein as being a Bayer abrasion ratio of 5 with respect to an uncoated plastic substrate (such as a polycarbonate), or alternatively by a Taber abrasion test with delta haze less than 15% after testing with a 500 g load and CS10F wheel at 500 cycles, (% haze being measured as per ASTM D1003). With these requirements met, the thickness of the hardcoating is preferably in the range of from about 1 to about 15 microns, such as about 2 to about 10 microns, and is most preferably between 2 and 7 microns. In one embodiment the minimum thickness is about 1 microns. In another embodiment the minimum thickness is about 2 microns.

The inventive article also comprises one or more intermediate layer(s) which can adjust the properties of the decorative coating. In such embodiments, the decorative coating can comprise a ‘stack’ of layers of different materials. For example, additional layers can tune the overall residual stress of the decorative coating, can alter the visual appearance of the decorative coating or can facilitate adhesion of the decorative coating to subsequent treatments or layers, such as the aforementioned base hardcoating. In certain embodiments, the decorative coating also comprises an adhesion controlling layer (also referred herein as adhesion promoting layer). In some embodiments, the decorative coating also comprises an optical modifying layer.

The one or more intermediate layers are located over the base hardcoating. In one embodiment two or more intermediate layers are present. In a preferred embodiment one intermediate layer is present. The one or more intermediate layers may be independently selected from the group of metals, metalloids and metal alloys including: chromium (Cr), aluminum (Al), titanium (Ti), nickel (Ni), molybdenum (Mo), zirconium (Zr), tungsten (W), silicon (Si), niobium (Nb), tantalum (Ta), vanadium (V), cobalt (Co), manganese (Mn), silver (Ag), zinc (Zn), indium (In), germanium (Ge), tin (Sn) and mixtures thereof; and an oxide, nitride, boride, fluoride or carbide thereof, and mixtures thereof. In one embodiment, the at least one or more intermediate layers are made formed from chromium, titanium, zirconium or mixtures thereof. In a preferred embodiment the article of the present invention comprises one layer made of Cr—Zr or Ti. In one embodiment the article of the invention only comprises one intermediate layer made from Cr—Zr. In one embodiment the article of the invention only comprises one intermediate layer made from Ti.

A CrZr layer can provide robust adhesion to the base hardcoating and also can achieve a wide range of film stresses (when tuned). In one embodiment the CrZr may be used even without a base hardcoating. A Ti layer can also be tuned to an acceptable and robust level of stress.

The one or more intermediate layers may have a thickness of about 10 nm to about 50 nm, such as about 15 nm to 45 nm, 15 nm to 40 nm or 15 nm to 35 nm each. In one embodiment, the overall thickness of all intermediate layers deposited may be in the ranges described above for the individual layers.

Also, the coated substrates are able to provide illuminated patterns for products, sometimes referred to as “hidden ‘til lit” (HTL), and back lighting in general, in suitable situations. In this respect, a desired optical effect can be achieved by selecting the correct % R and % T such that a light can be shone through a coating to produce an illuminated pattern. However, when the rear illumination is not present, the visual appearance of the product is such that it appears uniform, such that there is no visible pattern present.

For example, the use of CrZr or Ti layers can both achieve HTL compatibility (e.g. 6-15% transmission is possible). The intermediate layers, such as CrZr and/or Ti layers, may also provide some opacity as the optical transmission may be too high for the correct reflected color.

It may also be desirable to permit selective light transmission through the coated plastic article. Therefore, in some embodiments, the method further comprises providing a mask to the plastic substrate to provide a portion of controlled light transmission. This mask can be provided on surface of the substrate underlying the decorative coating. The mask may comprise an opaque coating (PVD, ink or paint), an adhesive masking film, film insert molding or two component injection molding. This can therefore provide visual symbols within the produced plastic article that can be illuminated by way of backlighting.

According to embodiments of the present disclosure, a TiN layer is located over the one or more intermediate layers. The TiN layer may have a thickness of about 10 nm to about 50 nm, such as about 15 nm to 45 nm, 15 nm to 40 nm or 15 nm to 35 nm. In one embodiment the layer thickness is about 15 nm to about 30 nm. In a further embodiment, the layer thickness is about 15 nm to about 25 nm. The latter may provide a 46-60% optical transmission. The TiN layer provides for a specific antique or tarnished copper look. In such an embodiment, the TiN layer may have the following color range (Table 1):

TABLE 1

| Reflected color metric as per CIELab, | | |
|---|---|---|
| illuminant A/2° | Maximum | Minimum |
| L* | 71 | 33 |
| a* | 20 | 2 |
| b* | 40 | 9 |

The color of the TiN layer is influenced by the TiN thickness and the nitrogen gas concentration. In embodiments, the TiN layer does not only comprise stoichiometric TiN but also other ratios of Ti:N. In one embodiment, the TiN layer may be a graded layer. In embodiments, a graded layer means that the either the concentration of Ti or N is increasing from the part directly located on the one or more intermediate layers to the outer part of the TiN layer, whereas the concentration of the other component is decreasing in the same direction. The grading may progress uniformly throughout the layer. In another embodiment the grading is progressing non-uniformly. For example, the grading may be achieved by continuously reducing or increasing the nitrogen gas flow into the reaction chamber. The skilled person will know how to change the nitrogen flow in order to achieve the desired grading. The TiN layer may have a refractive index and an extinction coefficient of approximately 1.35 and 2.76 at 632.8 nm.

In embodiments, an SiO₂ layer or PECVD HMDSO+O₂ etch layer is located over the TiN layer. These layers are required to make a protective hardcoating, that is the outer lay of the layer stack, adhere to the article, as generally such protective hardcoating would not adhere to layers such as Cr, CrZr, Ti, TiN, or the like. Thus, with the layer design the protective hardcoating can be fixedly and permanently attached to the subjacent layer(s). In one embodiment, a SiO₂ layer is located over the TiN layer. In an embodiment, a PECVD HMDSO+O₂ etch layer is located over the TiN layer.

Generally, a sputtering processes run in the same PVD chamber is limited with regard to the number of target materials. For example, industry standard PVD apparatuses can only fit 2 target materials at one given time. That means that, for example, SiO₂ and Ti/TiN can be run together (as, e.g., in the sputtering apparatus the Si targets usually are replaced with Ti targets), but then CrZr will not be available. Thus, for additional sputtering a CrZr layer a split process needs to be applied. Therefore, the system needs to be vented and reloaded at a later time for CrZr deposition.

To avoid the above preparation difficulties, a PECVD HMDSO process with an oxygen post etch can be used to replace the sputtered SiO₂ layer with a PECVD HMDSO+O₂ etch. This achieves excellent adhesion and passes all vehicle exterior tests (also a 1 year cycle equivalent accelerated UV test). The etched HMDSO layer may be used as an adhesion promoter between the TiN layer and the topcoat. It can also be used as a stress controlling layer similar to SiO₂.

The SiO₂ layer or PECVD HMDSO+O₂ etch layer is overcoated with a protective hardcoating. The protective hardcoating forms the forwardmost coating of the produced article when in use. Accordingly, the protective coating is exposed to the elements. This layer may further enhance the abrasion resistance, fingerprint resistance and ‘easy clean’ functionality. For example, a protective layer may be formed from a material exhibiting the following characteristics, including hydrophobic, hydrophilic, lipophobic, lipophilic and oleophobic characteristics or combinations thereof, and may include a hardcoating (with or without a matting additive (particles)) such as that mentioned above. An abrasion resistant hardcoating is one that reduces damage due to impacts and scratching. Abrasion resistance can be measured through tests such as ASTM F735 “Standard Test Method for Abrasion Resistance of Transparent Plastics and Coatings Using the Oscillating Sand Method”, ASTM D4060 “Standard Test Method for Abrasion Resistance of Organic Coatings”, by the Taber Abrader, or by using the well-known Steel wool Test.

Suitable materials for such a protective hardcoating may be the materials mentioned above for the base hardcoating. In one embodiment, the protective hardcoating may be a fluoro polymer based coatings deposited via evaporation or liquid transfer techniques, or a liquid hardcoating applied via spin, dip, spray or flow coating techniques, with or without particulate additives for haze control (matt additive). In one embodiment, a spray coating technique is used for applying the protective hardcoating. Commercially available hard coats include Momentive hard coats e.g. UVHC3000, UVHC5000, PHC587B/C, PHCXH100P and AS4700F, Mitsubishi hard coats, e.g. PH-800, or KCC hard coats, e.g. KUV-5000, but are not limited thereto. Each of these coatings has differing abrasion resistance, weatherability performance and deposition parameters. Accordingly, a skilled person will be able to select the appropriate coating for the intended purpose of the plastic article. In some embodiments, the hard coating is Momentive PHC587B or AS4700F. In a preferred embodiment, the hard coating is Momentive PHC587B.

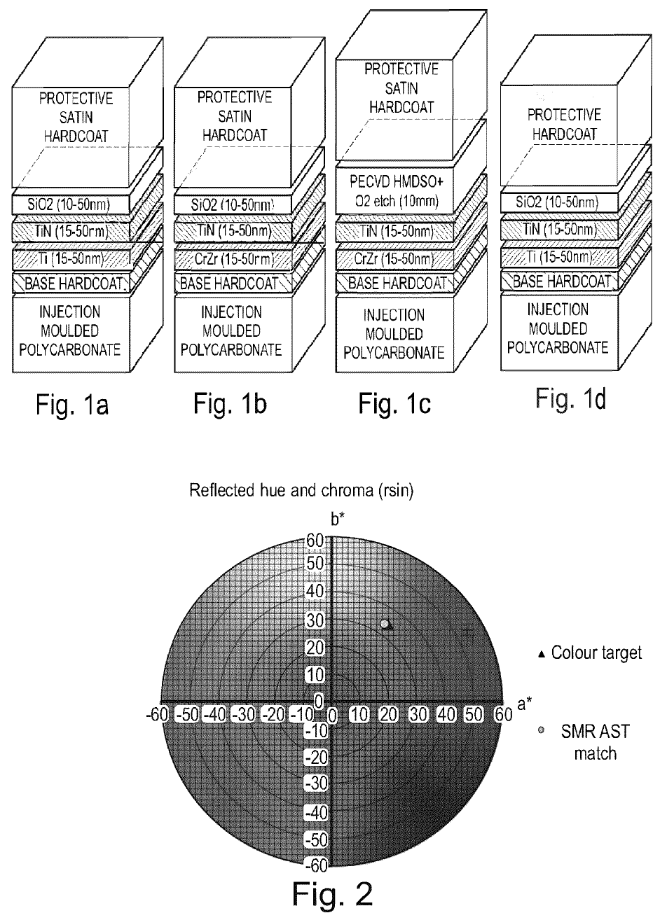

As shown in FIGS. 1a to 1c the protective layer in form of the protective hardcoat might provide in some embodiments a satin effect. In some embodiments the satin effect is provided as described later. The satin effect is however optional and in some embodiments the protective hardcoat does not provide the satin effect as the one shown in FIG. 1d. This hardcoat can be any general hardcoat that in some embodiments provides the before described characteristics and/or materials.

In one embodiment, the article comprises:
a polycarbonate substrate;
an optional base hardcoating located over the substrate;
a CrZr layer located over the hardcoating;
a TiN layer located over the CrZr layer;
a PECVD HMDSO+O₂ etch layer located over the TiN layer; and
a protective hardcoating located over the PECVD HMDSO+O₂ etch layer.

In one embodiment, the article comprises:
a polycarbonate substrate;
an optional base hardcoating located over the substrate;
a Ti layer located over the hardcoating;
a TiN layer located over the Ti layer;
a PECVD HMDSO+O₂ etch layer located over the TiN layer; and
a protective hardcoating located over the PECVD HMDSO+O₂ etch layer.

In one embodiment, the above articles comprise a base hardcoating.

A refinement to the visual appearance can also be achieved by patterning the substrate. For example, through the use of a patterned injection mold, a pattern can be formed on the front surface of a substrate. An example of a desirable optical effect is to replicate brushed stainless steel, and it has been found that parallel lines of random length (between 1 and 5 cm) positioned closely adjacent each other can achieve this appearance when subsequently coated with the present disclosure.

The application of the protective coating can influence the stress of the decorative coating. Therefore, in some embodiments, the residual stress of the decorative coating is the residual stress prior to any further treatment of the decorative coating, and particularly before application of the protective coating. Further, a skilled person will appreciate that the application of the protective coating can be modified to influence any additional stresses applied to the coated plastic article as a result of the protective coating. As known in the art, the protective coating itself may have residual stress when cured and this can be modified during application of the protective coating. Some examples of parameters that can be adjusted during application of the protective coating including the means of application (e.g. dip coating or spray coating), single-sided or double-sided application of the coating, the thickness of the applied coating, the use of a primer prior to application of the coating, the temperature of curing of the protective coating and the cooling rate of the coating (depending on the nature of the applied coating). Each of these factors can be changed, based on what is known in the art and the results can be assess based on known methods for assessing residual stress, including the method exemplified herein.

The protective coating, when applied over the decorative coating, can modify the appearance of the coating. In some embodiments, the protective coating incorporates a matting additive which is applied to coated plastic article. In this respect, it is known that a matt effect is achieved due to the diffusion effect produced by the small (usually ˜5 μm) particles of a matt additive. By alteration of the protective coating through the addition of matting additives a “satin” appearance can also be achieved. This is characterized by a significant diffuse reflected component (for example diffuse reflection between 10% and 30%, preferably 16% and a Specular Reflection of ˜8%). For example, a Tospearl 2000B loading may be used in e.g. 1.5% w/w for both PHC587B and AS4700F. In one embodiment the loading is 3.5%.

In one embodiment, an antique copper coating should be provided, that has HTL compatibility. As can be seen from FIGS. 1a to 1c, the use of an CrZi or Ti intermediate layer together with a TiN layer and a SiO₂ or PECVD HMDSO+O₂ etch layer provides a close antique copper color match. FIG. 2 provides the color match chart of these articles and shows that the color target (indicated by a black triangle) and the color of the articles of FIGS. 1a to 1c (indicated by a circle) perfectly overlap and match.

Preferred deposition methods that may be adopted for applying the multiple layers of the inventive article can be chosen from any suitable vacuum vapour deposition systems, such as thermal evaporation, electron beam evaporation (with or without ion beam assistance) or sputter deposition. Sputter deposition is the preferred method. Additionally, the surface of the plastic substrate may first be subjected to a surface treatment to improve adhesion. The surface treatment may be selected from any of plasma discharge, corona discharge, glow discharge and UV radiation.

The preferred optical thickness of each individual layer of the inventive article will of course depend on the desired optical effect. Therefore, for each different product, the expectation is that there will be a different set of “preferred optical thicknesses”.

In some embodiments, the overall residual stress of the decorative coating will be compressive (when measured in the absence of a protective hardcoating).

The residual stress within a film can be measured and is usually reported as a pressure (e.g. MPa). It can also be reported as displacement which represents the deflection of the underlying substrate after the coating is applied. The displacement is determined by the stress within the coating, the thickness of the coating and the properties of the underlying substrate. Accordingly, a thicker coating having a lower stress profile (as measure in MPa) can exert the same stress displacement on a substrate as a thinner coating with a higher stress profile. Therefore, in some embodiments, the residual stress of the decorative coating is measured as stress displacement. In some embodiments, the stress displacement is measure using a glass slide as the substrate. In some embodiments, the thickness of the glass slide is about 150 μm.

In some embodiments, the decorative coating is deposited under conditions that result in a residual film stress displacement of less than or equal to −50 μm, when deposited. In some further embodiments, the decorative coating is deposited under conditions that result in a residual film stress displacement of less than or equal to −240 μm, when deposited. In some further embodiments, the decorative coating is deposited under conditions that result in a residual film stress displacement of less than −765 μm, when deposited.

In this respect, in this stress range it has been found that a coated substrate will exhibit good performance throughout durability tests, such as salt spray, thermal shock, dry heat, immersion and humidity tests. Throughout this specification, this range will be referred to as “the desired stress window”. Having said that, an alternative range for the desired stress window is less than −6 MPa, or less than −63 MPa, or less than −76 MPa, or less than −100 MPa, or less than −110 MPa, or less than −112, or less than 160 MPa. Furthermore, the lower bounds of the stress window may be −360 MPa or greater, −359 MPa or greater, −300 MPa or greater, −250 MPa or greater, or −200 MPa or greater. Further combinations of these ranges are also contemplated by the present invention. For example the stress window may be between 0 MPa to −300 MPa; −63 MPa to −300 MPa, −75 MPa to −300 MPa, −110 MPa to −300 MPa or 0 MPa to −250 MPa etc.

In one embodiment the residual stress can also be compressive.

In one form, the system can be tuned to achieve the desired stress window by optimizing the deposition parameters of one or more of its layers. These parameters include sputter power, gas pressure, nitrogen gas doping and coating thickness. Stress can also be tuned to be more compressive (or less tensile) by introducing a thermal stress component by way of substrate heating, or by conducting a pre-treatment process directly before the deposition of the stress controlling system. The interaction of the stress controlling system with the spectrally controlling system is complex and the tuning of the overall residual stress is ideally conducted with reference to the entire decorative coating being a complete coating ‘stack’.

In this respect, the overall residual stress is the measured stress profile of layers as a complete stack deposited on a glass microscope cover slide. The stress measurement is obtained by placing the glass slide into a stress measurement device (such as a Sigma Physik SIG-500SP) before and after coating deposition.

Embodiments of the article of the present disclosure can be used in several different applications. In one embodiment the article is used in automotive applications. On one embodiment the article is used for automotive badges, door finishers, instrument panel, automotive mirrors and the like, but is not limited thereto.

In terms of possible uses for a decoratively coated plastic substrate in accordance with embodiments of the present disclosure, as foreshadowed above the coated plastic substrates can be used as designer surfaces on a variety of consumer goods including premium automotive interior and exterior trim components, consumer and household goods, as well as fashionable household electronic products, and either as partial or full surfaces for those goods.

In one embodiment, a method of manufacturing an article is disclosed that comprises the steps of:
a) forming a substrate having a front surface;
b) optionally coating a hardcoating onto the front surface of the substrate;
c) forming one or more intermediate layers on the hardcoating;
d) coating a TiN layer onto the one or more intermediate layers;
e) coating a SiO₂ layer or a layer using PECVD HMDSO+O₂ etching technology on the TiN layer; and
f) coating a protective hardcoating layer on the layer prepared in step e).

In one embodiment step b) is present.

Variations and modifications of the foregoing are within the scope of the present disclosure. It is understood that the disclosure disclosed and defined herein extends to all alternative combinations of two or more of the individual features mentioned or evident from the text and/or drawings. All of these different combinations constitute various alternative aspects of the present disclosure. The embodiments described herein explain the best modes known for practicing the teaching of the present disclosure and will enable others skilled in the art to utilize the teaching of the present disclosure. The claims are to be construed to include alternative embodiments to the extent permitted by the prior art. The invention is capable of other embodiments and of being practiced or being carried out in various ways. Also, it is understood that the phraseology and terminology used herein are for the purpose of description and should not be regarded as limiting. The use herein of “including”, “comprising” and variations thereof is meant to encompass the items listed thereafter and equivalents thereof, as well as additional items and equivalents thereof.

### EXAMPLES

### Example 1—Desired Optical Effect—Copper Spectrally Reflected Appearance with High % T

### Substrate Preparation

An injection molded polycarbonate substrate is first cleaned through a commercial ultrasonic cleaning system with detergent. A final rinse in distilled water is required in a clean (dust free) environment. The substrate is then dip coated in a Momentive PHC-587B at a withdrawal rate of 10 mm/s. A flash-off time of 10 minutes allows solvents to slowly evaporate and the part to be largely tack free. The substrate is then moved to a curing oven for 45 minutes at 130° C. Subsequent coatings are performed within a 48 hour period so as to avoid aging/contamination of the hardcoating.

### Decorative Coating

The substrate is loaded into a batch type vacuum sputter coater, (PylonMET VXL) which consists of a single coating chamber in which the samples are placed, evacuated and coated. Within this chamber the samples were evacuated to a pressure below 8×10−5 mbar. There was a target to substrate distance of 110 mm and the following were the deposition conditions:

TABLE 1
Decorative layer coating parameters (phase 1 interior development)

| | Stack 1a and 1b | | | | Stack 2 | | | |
|---|---|---|---|---|---|---|---|---|
| | | | | Layer 3 | | | | Layer 3 |
| | | | | (applied | | | | (applied |
| | | | | after 1 | | | | after 1 |
| | Pre- | | | day at | Pre- | | | day at |
| | Treat- | Layer | Layer | atmo- | Treat- | Layer | Layer | atmo- |
| Parameter | ment | 1 | 2 | sphere) | ment | 1 | 2 | sphere) |
| Glow discharge electrodes | 3 | | | | 3 | | | |
| (kW-Stainless steel) | | | | | | | | |
| Chromium/zirconium | | | | | | 45 | | |
| (98.5/1.5at %) target | | | | | | | | |
| power (kW) | | | | | | | | |
| Dual rotatable Titanium | | 30 | 30 | | | | 30 | |
| target (99.90% purity) | | | | | | | | |
| target power (kW) | | | | | | | | |
| Dual rotatable Silicon | | | | 18 | | | | 18 |
| target (99.90% purity) | | | | | | | | |
| target power (kW) | | | | | | | | |
| Total Gas flow (sccm) | 800 Ar | 200 Ar | 600 N2 | 100 Ar | 800 Ar | 240 Ar | 600 N2 | 100 Ar |
| | 100 O2 | | | 200 O2 | 100 O2 | | | 200 O2 |
| RPM | 6 | 12 | 12 | 24 | 6 | 24 | 12 | 24 |
| Number of rounds | 12 | 19 or | 62 | 20 | 12 | 6 | 70 | 20 |
| | | 30 | | | | | | |
| Base Pressure (mbar) | 8e−5 | 3e−5 | 3e−5 | 3e−5 | 8e−5 | 3e−5 | 3e−5 | 3e−5 |
| Run Pressure (mbar) | 1e−2 | 2e−3 | 2e−3 | 1.6e−3 | 1e−2 | 2e−3 | 2e−3 | 1.6e−3 |
| Thickness (nm) | 0 | 20 or | 25 | 35 | 0 | 25 | 25 | 35 |
| | | 35 | | | | | | |

| | | |
|---|---|---|
| Residual film stress | 1717.5 um (compressive) | 1903.5 um (compressive) |
| displacement (um) | | |
| Reflected L*a*b* | L* 40.75 or L* 41.7 | L* 43.31 |
| when satin coated | a* 17.81 or a* 14.23 | a* 18.48 |
| (CIEL*a*b*, illuminant | b* 27.59 or b* 21.43 | b* 27.96 |
| A, 2° observer) | | |
| Transmitted L*a*b* | L* 14.58 or L*36.12 | L* 37.08 |
| when satin coated | a* 0.98 or a* −0.3 | a* 0.52 |
| (CIEL*a*b*, illuminant | b* 7.32 or b* 5.64 | b* 7.69 |
| A, 2° observer) | | |

TABLE 2
Decorative layer coating parameters (phase 2 exterior development)

| | Stack 3 | | | | Stack 4a and 4b | | | | |
|---|---|---|---|---|---|---|---|---|---|
| | Pre- | | | | Pre- | | | | Post- |
| | Treat- | Layer | Layer | Layer | Treat- | Layer | Layer | Layer | treat- |
| Parameter | ment | 1 | 2 | 3 | ment | 1 | 2 | 3 | ment |
| Glow discharge electrodes | 3 | | | | 3 | | | 5 | 3 |
| (kW-Stainless steel) | | | | | | | | | |
| Chromium/zirconium | | | | | | 53 | | | |
| (98.5/1.5at %) | | | | | | | | | |
| target power (kW) | | | | | | | | | |
| Titanium (99.90% purity) | | 12.5 | 12.5 | | | | | | |
| target power (kW) | | | | | | | | | |
| Dual rotatable Titanium | | | | | | | 30 | | |
| target (99.90% purity) | | | | | | | | | |
| target power (kW) | | | | | | | | | |
| Dual rotatable | | | | 18 | | | | | |
| Silicon target | | | | | | | | | |
| (99.90% purity) target | | | | | | | | | |
| power (kW) | | | | | | | | | |
| Total Gas flow (sccm) | 800 Ar | 300 Ar | 450 N2 | 100 Ar | 800 Ar | 550 Ar | 600 N2 | 210 | 300 O2 |
| | 100 O2 | | | 200 O2 | 100 O2 | | | HMDSO | |
| RPM | 6 | 24 | 24 | 24 | 6 | 24 | 12 | 24 | 12 |
| Number of rounds | 12 | 65 | 160 | 15 | 12 | 8 | 30 or 70 | 8 | 4 |
| Base Pressure (mbar) | 8e−5 | 3e−5 | 3e−5 | 3e−5 | 8e−5 | 3e−5 | 3e−5 | 3e−5 | 2e−2 |
| Run Pressure (mbar) | 1e−2 | 2e−3 | 2e−3 | 1.6e−3 | 1e−2 | 3e−3 | 2e−3 | 6e−2 | 6e−2 |
| Thickness (nm) | 0 | 25 | 25 | 28 | 0 | 25 | 15 or 25 | 8 | n/a |

| | | |
|---|---|---|
| Residual film stress | −263.3 um (tensile) | −117.7 um (tensile) or 562.2 (compressive) |
| displacement (um) | | |
| Reflected L*a*b* | L* 44.42 | L* 66.19 or 44.57 |
| when satin coated | a* 13.38 | a* 4.21 or 18.28 |
| (CIEL*a*b*, illuminant | b* 30.19 | b* 18.41 or 31.87 |
| A, 2° observer) | | |
| Transmitted L*a*b* | L* 25.09 | L* 26.18 or 25.6 |
| when satin coated | a* 0.81 | a* 2.37 or 1.22 |
| (CIEL*a*b*, illuminant | b* 6.31 | b* 2.02 or 7.52 |
| A, 2° observer) | | |

### Protective Satin Coating—Interior Variants

To provide a satin metallic look a protective hard coat was applied which included an additive that resulted in diffusion of visible light. Specifically, the following parameters were used

TABLE 3
Protective satin layer coating parameters (interior)

| | Layer 1 |
|---|---|
| Material | Momentive PHC-587B + Tospearl |
| | 2000B at a 3.5% wt/wt |
| Deposition Method | Spray Coated and cured at 130° C. |
| Thickness (μm) | 8 to 16 |

### Protective Satin Coating—Exterior Variants

To provide a satin metallic look a protective hard coat was applied which included an additive that resulted in diffusion of visible light. Specifically, the following parameters were used

TABLE 4
Protective satin layer coating parameters (exterior)

| | Layer 1 |
|---|---|
| Material | Momentive AS4700F + Tospearl |
| | 2000B at a 3.5% wt/wt |
| Deposition Method | Spray Coated and cured at 127° C. |
| Thickness (μm) | 8 to 12 |

### Example 2: Stress Testing

The tests performed and the outcomes are summarized in Table 5 below.

TABLE 5
Durability testing of coated samples

| | | Result | | | | | |
|---|---|---|---|---|---|---|---|
| | | Interior | | | Exterior | | |
| | | Stack | Stack | Stack | Stack | Stack | Stack |
| Test | Method | 1a | 1b | 2 | 3 | 4a | 4b |
| Cross hatch | ISO 2409 using | PASS | PASS | PASS | PASS | PASS | PASS |
| adhesion | a single-blade | | | | | | |
| | cutting tool and | | | | | | |
| | 3M Scotch 8981 | | | | | | |
| | tape. Adhesion | | | | | | |
| | rating ≤1. | | | | | | |
| Abrasion— | A 30 cm long | PASS | PASS | PASS | PASS | PASS | PASS |
| steel wool | skeen of 0 | | | | | | |
| | grade steel wool | | | | | | |
| | folded into a | | | | | | |
| | 40 mm × 40 mm | | | | | | |
| | square pad and | | | | | | |
| | fitted to a | | | | | | |
| | Sutherland | | | | | | |
| | Ink Rub | | | | | | |
| | Tester. 1.9 kg of | | | | | | |
| | force is applied | | | | | | |
| | onto the surface | | | | | | |
| | of the sample | | | | | | |
| | for 75 cycles. | | | | | | |
| Abrasion— | A 30 cm long | PASS | PASS | PASS | PASS | PASS | PASS |
| scuff | skeen of 0000 | | | | | | |
| | grade steel wool | | | | | | |
| | folded into a | | | | | | |
| | 40 mm × 40 mm | | | | | | |
| | square pad and | | | | | | |
| | fitted to a | | | | | | |
| | Sutherland | | | | | | |
| | Ink Rub | | | | | | |
| | Tester. 0.9 kg of | | | | | | |
| | force is applied | | | | | | |
| | onto the surface | | | | | | |
| | of the sample | | | | | | |
| | for 10 cycles. | | | | | | |
| Chemical | Soak a 300 × | PASS | PASS | PASS | PASS | PASS | PASS |
| resistance | 300 mm cotton | | | | | | |
| | cloth in 50 mL | | | | | | |
| | of each | | | | | | |
| | reagent, apply | | | | | | |
| | reagent to the | | | | | | |
| | coated surface | | | | | | |
| | and store | | | | | | |
| | at laboratory | | | | | | |
| | ambient | | | | | | |
| | temperature for | | | | | | |
| | 48 hrs (unless | | | | | | |
| | noted otherwise) | | | | | | |
| | following which | | | | | | |
| | the reagent | | | | | | |
| | shall be | | | | | | |
| | removed | | | | | | |
| | from the | | | | | | |
| | coated surface | | | | | | |
| | which is then | | | | | | |
| | wiped with | | | | | | |
| | cheesecloth for | | | | | | |
| | 10 cycles. | | | | | | |
| Water | Immerse a | PASS | PASS | PASS | PASS | PASS | PASS |
| immersion | sample for | | | | | | |
| | 320 h in water | | | | | | |
| | kept at 40° C. | | | | | | |
| Short term | Expose sample | PASS | PASS | PASS | PASS | PASS | PASS |
| heat | to 110° C. for | | | | | | |
| | 7 hours. | | | | | | |
| Thermal | 10x cycles of | PASS | PASS | PASS | PASS | PASS | PASS |
| cycling | 75° ± 2° C. | | | | | | |
| | 4 h => 38° ± | | | | | | |
| | 2° C., 95% ± 5% | | | | | | |
| | RH 16 h => | | | | | | |
| | −30° ± | | | | | | |
| | 2° C. 4 h. | | | | | | |
| Thermal | 200x Cycles | PASS | PASS | PASS | PASS | PASS | PASS |
| Shock | −40° C. | | | | | | |
| | to 85° C., | | | | | | |
| | 1 hr/cycle. | | | | | | |
| Salt Spray | Salt Spray for | PASS | PASS | PASS | PASS | PASS | PASS |
| | 480 hours as per | | | | | | |
| | ASTM B 117. | | | | | | |
| Russian | 336 hours | PASS | PASS | PASS | PASS | PASS | PASS |
| Mud | exposure to | | | | | | |
| | CaCl2 + Kaolin | | | | | | |
| | powder | | | | | | |
| High | Expose sample | PASS | PASS | PASS | PASS | PASS | PASS |
| temperature | to 80° C. for | | | | | | |
| ageing | 500 hours. | | | | | | |
| Low | Expose sample | PASS | PASS | PASS | PASS | PASS | PASS |
| temperature | to −40° C. for | | | | | | |
| ageing | 240 hours. | | | | | | |
| Humidity | Expose sample | PASS | PASS | PASS | PASS | PASS | PASS |
| ageing | to 40° C./95% | | | | | | |
| | RH for 500 | | | | | | |
| | hours. | | | | | | |
| Condensate | Expose sample | PASS | PASS | PASS | PASS | PASS | PASS |
| | to 40° C. for | | | | | | |
| | 240 hours as per | | | | | | |
| | DIN EN ISO | | | | | | |
| | 6270-2 CH | | | | | | |
| UV | 1250 kJ/m2 of | PASS | PASS | PASS | N/A | N/A | N/A |
| resistance | Xenon Arc | | | | | | |
| Interior | exposure as per | | | | | | |
| | SAEJ2527. | | | | | | |
| | Adhesion rating | | | | | | |
| | ≤1. | | | | | | |
| UV | 3960 kJ/m2 of | N/A | N/A | N/A | PASS | PASS | PASS |
| resistance | Xenon Arc | | | | | | |
| Exterior | exposure as per | | | | | | |
| | SAEJ2527. | | | | | | |
| | Adhesion rating | | | | | | |
| | ≤1. | | | | | | |

As can be seen from Table 5, the prepared articled passed all necessary tests.

It is claimed:

1. An article having a decorative coating, comprising:
a plastic substrate having a front surface;
an optional base hardcoating located over the front surface;
one or more intermediate layers located over the hardcoating;
a TiN layer located over the one or more intermediate layers;
an SiO₂ layer or PECVD HMDSO+O₂ etch layer located over the TiN layer; and
a protective hardcoating located over the SiO₂ or PECVD HMDSO+O₂ etch layer.

2. The article according to claim 1, wherein the plastic substrate is formed from a material selected from the group consisting of polyacrylate, polyester, polystyrene, polyethylene, polypropylene, polyamides, polyimides, polycarbonate, epoxy, phenolic, acrylonitrilebutadiene-styrenes, acetyl materials, poly (2,2′-dihydroxyphenylpropane) carbonate, polydiethyleneglycol bis(allyl carbonate), polymethylmethacrylate and polystyrene polycarbonate, and blends thereof.

3. The article according to claim 1, wherein the base hardcoating is formed from one or more abrasion resistant layers, the abrasion resistant layers being formed from a material selected from the group consisting of an organo-silicon, an acrylic, a urethane, melamine and a SiOₓC_{y}H_{z}

4. The article according to claim 3, wherein the base hardcoating has a thickness in the range of from about 1 micron to about 15 microns.

5. The article according to claim 1, wherein the one or more intermediate layers are layers selected from the group consisting of chromium, aluminum, titanium, nickel, molybdenum, zirconium, tungsten, silicon, niobium, tantalum, vanadium, cobalt, manganese, silver, zinc, and mixtures thereof; and an oxide, nitride, boride or carbide thereof, alloys thereof and mixtures thereof.

6. The article according to claim 5, wherein the one or more intermediate layers are formed from chromium, titanium, zirconium or mixtures thereof.

7. The article according to claim 6, comprising one intermediate layer made from CrZr or Ti.

8. The article according to claim 1, wherein the one or more intermediate layers has a thickness in the range of from about 20 nm to about 80 nm.

9. The article according to claim 1, wherein the TiN layer has a thickness of about 15 nm to about 50 nm.

10. The article according to claim 1, wherein the protective hardcoating is Momentive AS4700F or Momentive PHC587B.

11. The article according to claim 1, wherein a PECVD HMDSO+O₂ etch layer is located over the TiN layer.

12. The article according to claim 1, wherein the article is for automotive applications.

13. A method of manufacturing an article, comprising:
(a) forming a substrate having a front surface;
(b) forming one or more intermediate layers on the hardcoating;
(c) coating a TiN layer onto the one or more intermediate layers;
(d) coating a SiO₂ layer or a layer using PECVD HMDSO+O₂ etching technology on the TiN layer; and
(e) coating a protective hardcoating layer on the layer prepared in step (d).

14. The method of claim 13, further comprising:
coating a hardcoating onto the front surface of the substrate;
